(19) United States
(12) Patent Application Publication
(10) Pub. No.: US 2020/0203084 A1
(43) Pub. Date: Jun. 25, 2020

(54) PHOTOELECTRIC CONVERSION ELEMENT

(71) Applicant: KABUSHIKI KAISHA TOSHIBA, Minato-ku (JP)

(72) Inventors: Haruhi OOOKA, Kawasaki (JP); Kenji Todori, Yokohama (JP); Kenji Fujinaga, Yokohama (JP)

(73) Assignee: KABUSHIKI KAISHA TOSHIBA, Minato-ku (JP)

(21) Appl. No.: 16/811,782

(22) Filed: Mar. 6, 2020

Related U.S. Application Data
(63) Continuation of application No. PCT/JP2018/034480, filed on Sep. 18, 2018.

(51) Int. Cl. H01G 9/20

(52) U.S. Cl. CPC H01G 9/2077

(57) ABSTRACT

A photoelectric conversion element comprises: a photoelectric conversion layer; a first compound layer including a first supporting member and a first compound, the first compound being supported by the first supporting member, being not in contact with the photoelectric conversion layer, and being liquid or gelatinous in an environment to use the element; and a second compound layer including a second supporting member and a second compound, the second compound being supported by the second supporting member, being not in contact with the photoelectric conversion layer and the first compound, and being liquid or gelatinous in the environment.

### CROSS-REFERENCE TO RELATED APPLICATIONS

This application is a continuation of prior International Application No. PCT/JP2018/034480 filed on Sep. 18, 2018; the entire contents of all of which are incorporated herein by reference.

### FIELD

Embodiments relate to a photoelectric conversion element.

### BACKGROUND

An organic/inorganic hybrid semiconductor such as an organic/inorganic hybrid perovskite compound is expected to be applied to photoelectric conversion elements such as a photovoltaics, a light emitting element, a photosensor, and an electromagnetic-wave sensor. An example of the organic/inorganic hybrid perovskite compound is a compound having a composition expressed, for example, by ABX₃. A B site is a divalent cation, and its examples include lead, tin and the like. In particular, a photoelectric conversion element using an organic/inorganic hybrid perovskite compound using lead has high photoelectric conversion efficiency. Further, a photoelectric conversion element using the organic/inorganic hybrid perovskite compound as an active layer can be manufactured at low temperature, and thus a substrate made of resin or the like can be used. Therefore, a light-weight and flexible photoelectric conversion element can be realized, thereby making it possible to install, for example, a conventional heavy silicon photovoltaics using a glass substrate which is insufficient in load-bearing capacity, on a building on which the photovoltaics was not able to be installed so far.

On the other hand, since lead is harmful, it is necessary to prevent lead from leaking due to, for example, breakage of the photovoltaics installed on the building. In particular, in the case of using resin or the like for a substrate, the substrate is likely to break and an encapsulating material is likely to peel off due to the influence of hailstorm or typhoon, resulting in leakage of lead. Further, the organic/inorganic hybrid perovskite compound is high in solubility in water, so that lead is likely to dissolve out, for example, by rainfall. ABX₃ is known to be easily decomposed into BX₂ due to the presence of water, and BX₂ being a decomposition product is also high in solubility in water. Examples of the harmful substance constituting the photoelectric conversion element include CdS, CdTe, CGS, GaAs and the like which are used as an active layer material, and lead and the like contained in solder used for a wiring material. The solubility of CdS with respect to 100 ml of neutral water is about 1×10⁻¹² g, whereas the solubility of BX₂ being the decomposition product of the organic/inorganic hybrid perovskite compound by water is about 1×10⁻³ to 1×10⁰ g, which is high solubility as compared with those of the other harmful substances constituting the photoelectric conversion element.

In a dye-sensitized photovoltaics using an electrolytic solution, the electrolytic solution is liquid, so that it is necessary to prevent leakage of the harmful substance due to, for example, breakage of the photovoltaics installed on the building. As explained above, a technique is demanded which prevents the leakage of the harmful substance due to the breakage of the photoelectric conversion element containing the harmful substance.

### BRIEF DESCRIPTION OF THE DRAWINGS

FIG. 1 is a view illustrating a structure example of a photoelectric conversion element;

FIG. 2 is a view illustrating a structure example of the photoelectric conversion element;

FIG. 3 is a view illustrating a structure example of the photoelectric conversion element;

FIG. 4 is a view illustrating a structure example of the photoelectric conversion element;

FIG. 5 is a view illustrating a structure example of the photoelectric conversion element;

FIG. 6 is a view illustrating a structure example of a photoelectric conversion layer;

FIG. 7 is a view illustrating a structure example of a compound layer;

FIG. 8 is a view illustrating a breakage example of the photoelectric conversion element;

FIG. 9 is a chart illustrating a typical chemical reaction formula of foaming polyurethane;

FIG. 10 is a chart illustrating a typical chemical reaction formula of foaming polyurea;

FIG. 11 is a view illustrating a structure example of the photoelectric conversion element;

FIG. 12 is a view illustrating a structure example of the photoelectric conversion element;

FIG. 13 is a view illustrating a structure example of the photoelectric conversion element;

FIG. 14 is a view illustrating a structure example of the photoelectric conversion element;

FIG. 15 is a chart illustrating a typical chemical reaction formula of one-component moisture-curing polyurethane;

FIG. 16 is a view illustrating a structure example of the photoelectric conversion element;

FIG. 17 is a view illustrating a structure example of the photoelectric conversion element;

FIG. 18 is a view illustrating a structure example of the photoelectric conversion element;

FIG. 19 is a view illustrating a structure example of the photoelectric conversion element; and

FIG. 20 is a view illustrating a structure example of the photoelectric conversion element.

### DETAILED DESCRIPTION

A photoelectric conversion element in an embodiment comprises: a photoelectric conversion layer; a first compound layer including a first supporting member and a first compound, the first compound being supported by the first supporting member, being not in contact with the photoelectric conversion layer, and being liquid or gelatinous in an environment to use the element; and a second compound layer including a second supporting member and a second compound, the second compound being supported by the second supporting member, being not in contact with the photoelectric conversion layer and the first compound, and being liquid or gelatinous in the environment.

Hereinafter, embodiments will be explained with reference to the drawings. Note that, in the embodiments, substantially the same constituent parts are denoted by the same reference signs and explanation thereof will be partly omitted in some case. The drawings are schematic, and a relation between thickness and planar dimension, a thickness ratio among parts, and so on are sometimes different from actual ones.

### First Embodiment

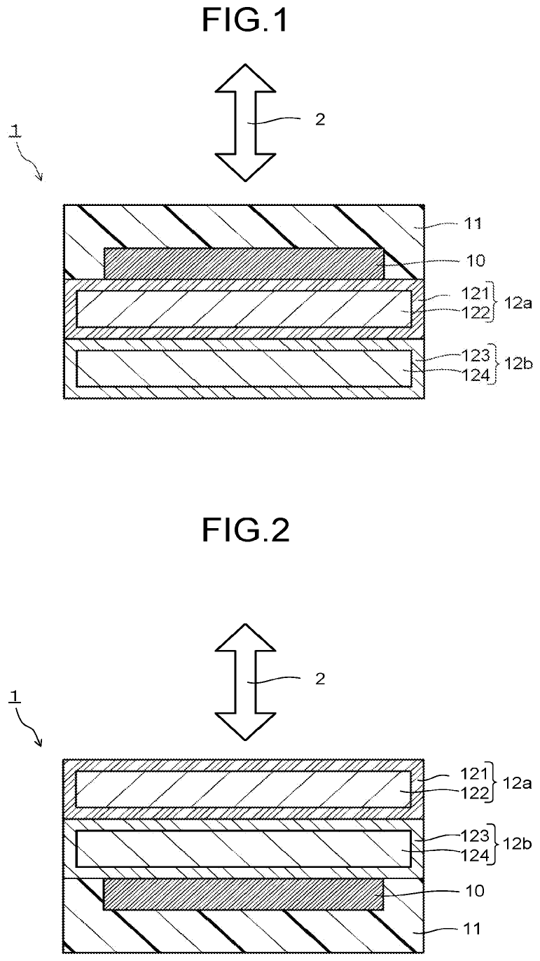

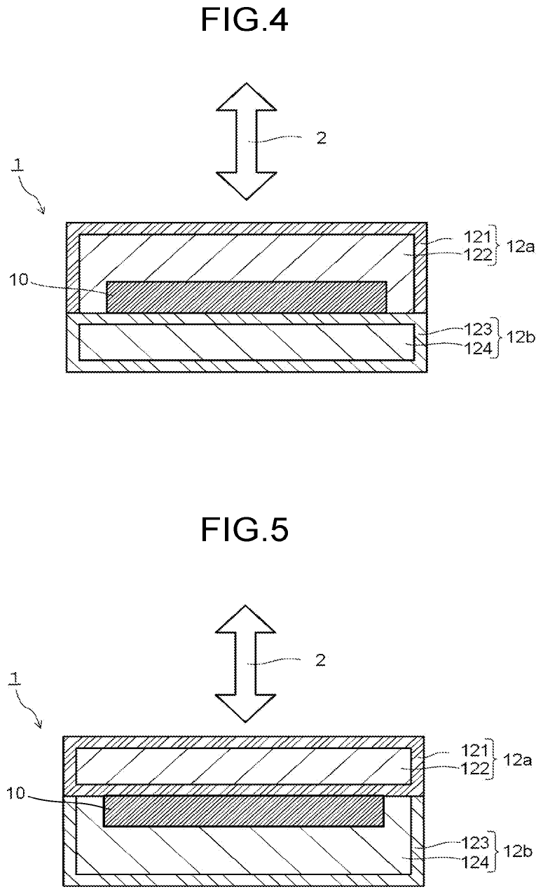

FIG. 1 to FIG. 5 are views illustrating structure examples of a photoelectric conversion element. Photoelectric conversion elements 1 illustrated in FIG. 1 to FIG. 3 each include a photoelectric conversion layer 10, an encapsulating member 11, a compound layer 12a, and a compound layer 12b. Photoelectric conversion elements 1 illustrated in FIG. 4 and FIG. 5 each include a photoelectric conversion layer 10, a compound layer 12a, and a compound layer 12b. A photovoltaics using an organic/inorganic hybrid perovskite compound will be explained here as the photoelectric conversion element 1, but the photoelectric conversion elements in the embodiments are also applicable to a dye-sensitized photovoltaics, a light emitting element, a photosensor, an electromagnetic wave sensor, a radiation ray sensor and so on.

When light 2 enters or exits, the photoelectric conversion layer 10 performs photoelectric conversion. The light 2 is, for example, sunlight. Further, in this specification, the light 2 includes light other than the visible light spectrum, electromagnetic wave, and radiation ray.

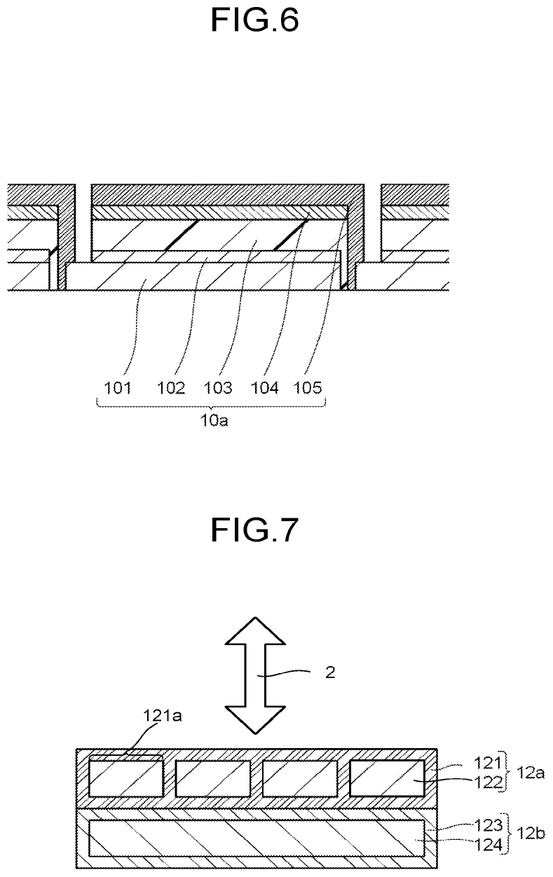

FIG. 6 is a cross-sectional schematic view illustrating a structure example of the photoelectric conversion layer 10. The photoelectric conversion layer 10 includes, for example, a plurality of cells 10a. The plurality of cells 10a are electrically connected to each other in serial connection. This can increase the output voltage.

Each of the plurality of cells 10a has an electrode 101, an intermediate layer 102 provided on the electrode 101, an active layer 103 provided on the intermediate layer 102, an intermediate layer 104 provided on the active layer 103, and an electrode 105 provided on the intermediate layer 104. The electrode 101 of one cell 10a is electrically connected to the electrode 105 of the cell 10a at the adjacent preceding stage. The electrode 105 of one cell 10a is electrically connected to the electrode 101 of the cell 10a at the adjacent subsequent stage. The intermediate layer 102 and the intermediate layer 104 do not always need to be provided. The electrode 101 and the electrode 105 may be provided on the entrance/exit side of the light 2 and its opposite side of the active layer 103 in a manner to support the active layer 103 therebetween, or may be arranged on either one side of the active layer 103 in a manner to be separated from each other, for example, arranged side by side alternately in a stripes form (for example, a so-called back-contact mode).

In the case where at least one of the electrode 101 and the electrode 105 has a light transmitting property, at least one of the electrode 101 and the electrode 105 is composed of a material having a light transmitting property and electrical conductivity. For example, a conductive metal oxide such as indium oxide, zinc oxide, tin oxide, indium tin oxide (ITO), fluorine-doped tin oxide (FTO), gallium-doped zinc oxide (GZO), aluminum-doped zinc oxide (AZO), indium-zinc oxide (IZO), or indium-gallium-zinc oxide (IGZO) is used. The electrode 101 may be a stack of a layer formed of the aforesaid material and a metal layer formed of metal such as gold, platinum, silver, copper, cobalt, nickel, indium, or aluminum, or an alloy containing any of these metals, within a range capable of maintaining the light transmitting property. The layer of the above material is formed by, for example, a vacuum deposition method, a sputtering method, an ion plating method, a CVD method, a sol-gel method, a plating method, a coating method, or the like.

The thickness of the electrode having the light transmitting property is not particularly limited, but is preferably 10 nm or more and 1 μm or less, and more preferably 30 nm or more and 300 nm or less. if the electrode is too thin, sheet resistance increases. If the electrode is too thick, light transmittance decreases and flexibility decreases, so that a crack or the like is likely to occur due to stress. It is preferable to select the film thickness of the electrode so that both of high light transmittance and low sheet resistance are obtained. The sheet resistance of the electrode is not particularly limited, but is typically 1000Ω/□ or less, preferably 500Ω/□ or less, and more preferably 200Ω/□ or less.

In the case where the electrode 101 or the electrode 105 does not have a light transmitting property, the electrode 101 or the electrode 105 is formed of metal such as platinum, gold, silver, copper, nickel, cobalt, iron, manganese, tungsten, titanium, zirconium, tin, zinc, aluminum, indium, chromium, lithium, sodium, potassium, rubidium, cesium, calcium, magnesium, barium, samarium, or terbium, an alloy containing any of these metals, a conductive metal oxide such as an indium-zinc oxide (IZO), or a carbon material such as graphene or carbon nanotube.

The layer of the above material is formed by, for example, a vacuum deposition method, a sputtering method, an ion plating method, a sol-gel method, a plating method, a coating method or the like. The thickness of the electrode is not particularly limited, but is preferably 1 nm or more and 1 μm or less. If the electrode is too thin, resistance becomes too high, thus possibly failing to sufficiently transmit the generated electric charges to an external circuit. If the electrode is too thick, its film formation takes a long time and accordingly the electrode material temperature increases, thus possibly damaging the active layer 103. The sheet resistance of the electrode is not particularly limited, but is preferably 500Ω/□ or less, and more preferably 200Ω/□ or less.

One of the intermediate layer 102 and the intermediate layer 104 has a function of selectively and efficiently transporting holes, and is a so-called hole transport layer, hole extraction layer, hole injection layer or the like. The other of the intermediate layer 102 and the intermediate layer 104 has a function of selectively and efficiently transporting electrons, and is a so-called electron transport layer, electron extraction layer, electron injection layer or the like.

Examples of the material of the hole transport layer include inorganic materials such as nickel oxide, copper oxide, vanadium oxide, tantalum oxide, and molybdenum oxide, and organic materials such as polythiophene, polypyrrole, polyacetylene, triphenylenediaminepolypyrrol, polyaniline, and derivatives of them, and are not particularly limited.

Examples of the usable material of the electron transport layer include inorganic materials such as zinc oxide, titanium oxide, and gallium oxide, organic materials such as polyethyleneimine and its derivative, and a carbon material such as the aforesaid fullerene derivative, and the material is not particularly limited.

The active layer 103 has a function of generating and separating electric charges using the energy of the emitted light 2. The active layer 103 generally decreases in photoelectric conversion efficiency due to contact with moisture or oxygen in many cases. Accordingly, the decreases in photoelectric conversion efficiency can be suppressed by encapsulating with another member.

In the case of applying the photoelectric conversion element 1, for example, to an organic/inorganic hybrid photovoltaics, the active layer 103 includes, for example, an organic/inorganic hybrid perovskite compound. An example of the organic/inorganic hybrid perovskite compound is a compound having a composition expressed, for example, by ABX₃. An A site is a monovalent cation, a B site is a divalent cation, and an X site is halogen. In the case where a tolerance factor t expressed by the following formula (1) is within a range of 0.75 or more and 1.1 or less, a three-dimensional perovskite crystal is obtained and high photoelectric conversion efficiency is obtained. In the following formula, a Shannon ionic radius is used, though there are several kinds of ionic radii.

t=(A site ionic radius+X site ionic radius)/{2^{1/2}×(B site ionic radius+X site ionic radius)} (1)

Examples of the A site include an organic amine compound such as CH₃NH₄, cesium, and rubidium. Examples of the B site include lead and tin. Use of lead can achieve high conversion efficiency. Examples of the X site include halogen elements such as iodine, bromine, and chlorine. Examples of a method for forming the active layer 103 include a method of vacuum depositing the aforesaid perovskite compound or its precursor, and a method of applying a solution in which the perovskite compound or its precursor is dissolved in a solvent and then heating and drying the solution. An example of the precursor of the perovskite compound is a mixture of methylammonium halide and lead halide or tin halide. The thickness of the active layer 103 is not particularly limited, but is preferably 10 nm or more and 1000 nm or less.

The encapsulating member 11 suppresses the contact between the photoelectric conversion layer 10 and a material such as gas, liquid or the like in a use environment. The encapsulating member 11 covers the photoelectric conversion layer 10. The encapsulating member 11 only needs to be able to suppress the contact between the photoelectric conversion layer 10 and the material in the use environment, and is composed using an arbitrary solid material or liquid material, a combination of them or the like. When the encapsulating member 11 needs to have a light transmitting property, an inorganic material such as non-alkali glass, quartz glass, or sapphire, or an organic material such as polyethylene (PE), polyethylene terephthalate (PET), polyethylene naphthalate (PEN), polyimide, polyamide, polyamide-imide, or a liquid crystal polymer is used as the constituent material. The encapsulating member 11 may be, for example, a rigid substrate composed of the inorganic material or the organic material, or may be a flexible substrate composed of the organic material or an ultrathin inorganic material.

A constituent member arranged closer to the entrance/exit side of the light 2 than the photoelectric conversion layer 10 is composed of using a material and a structure having a transmitting property with respect to the light 2. For example, in the case where the configuration in FIG. 1 is used as a photovoltaics, the encapsulating member 11 is composed using a material having a light transmitting property with respect to the sunlight. Further, in the case where the electrode 105 is arranged closer to the entrance/exit side of the light 2 than the photoelectric conversion layer 10, the electrode 105 is composed using a material having a light transmitting property.

The compound layer 12a and the compound layer 12b have a function as a leakage prevention layer which prevents leakage of a harmful substance such as lead contained in the photoelectric conversion layer 10 accompanying the breakage of the photoelectric conversion element 1. Examples of the breakage of the photoelectric conversion element 1 include formation of a flaw reaching the photoelectric conversion layer 10, fracture, peeling of the encapsulating member 11 and so on.

The compound layer 12a includes, for example, a supporting member 121 and a compound 122 supported by the supporting member 121. The compound 122 is superimposed on the photoelectric conversion layer 10.

The compound layer 12b includes, for example, a supporting member 123 and a compound 124 supported by the supporting member 123. The compound 124 is not in contact with the compound 122 and superimposed on the photoelectric conversion layer 10. Note that the compound 122 and the compound 124 may be supported to be not in contact with each other by one supporting member.

The supporting member 121 and the supporting member 123 have a function as a partition. The supporting member 121 and the supporting member 123 only need to break along with the breakage of the photoelectric conversion element 1, and is composed of using, but not limited to, an organic material such as polyethylene (PE), polyethylene terephthalate (PET), or an inorganic material such as glass, quartz, or sapphire. Further, the supporting member 121 and the supporting member 123 may have a hybrid structure composed of the organic material or an ultrathin inorganic material.

FIG. 7 is a view illustrating another structure example of the compound layer 12a. In FIG. 7, the supporting member 121 has a plurality of spaces 121a partitioned from each other, a compound high in fluidity is used as a main component of the compound 122, and the compound 122 is filled in each of the plurality of spaces 121a. The provision of the plurality of spaces 121a can prevent the compound 122 in the compound layer 12a from unevenly distributed due to the gravity in the case where the pressure applied to the compound layer 12a varies within the plane or the case where the photoelectric conversion element 1 is installed obliquely with respect to the gravity horizontal direction. The structure is not limited to this, but the same structure may be provided, for example, in the compound layer 12b.

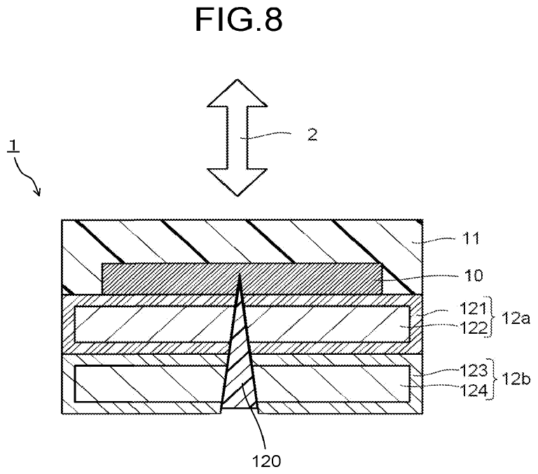

FIG. 8 is a view illustrating a breakage example of the photoelectric conversion element 1. The compound 122 and the compound 124 come into contact with each other, for example, accompanying the breakage of the photoelectric conversion element 1 to cause a polymerization to thereby form a polymer 120. The polymer 120 fills a broken part of the photoelectric conversion element 1. This can prevent leakage of the harmful substance from the photoelectric conversion element 1. The polymer 120 may fill the whole space of the flaw drawn in a triangular shape as an example as illustrated in FIG. 8, or may fill only a part of the space of the flaw to cut off the photoelectric conversion layer 10 from the atmosphere in the use environment. In the photoelectric conversion element in the first embodiment, the leakage of the harmful substance accompanying the breakage of the photoelectric conversion element is prevented using a so-called two-component curing compound layer which causes a polymerization by two kinds of compounds coming into contact with each other.

As the compound 122 and the compound 124, materials which come into contact with each other due to the breakage of the photoelectric conversion element 1 to cause a polymerization to thereby form the polymer 120 are used. Even when the photoelectric conversion element 1 is exposed to a large amount of water due to rainfall or snowfall or dew condensation after the photoelectric conversion element 1 is broken, the formation of the polymer 120 can prevent the broken part of the photoelectric conversion element 1 filled with the polymer 120 from being exposed again. In short, the polymer 120 is preferably the one which is insoluble in water and water is unlikely to permeate.

In order to make the compound 122 and the compound 124 spontaneously come into contact when the photoelectric conversion element 1 is broken, at least one of the compound 122 and the compound 124 preferably has a main component having fluidity in the use environment and more preferably is in a liquid state or a gelatinous state. As for the use environment, the air pressure and the temperature change according to the latitude or the altitude in the case where the photoelectric conversion element 1 is used, for example, as a photovoltaics installed on the roof of a building. The water pressure and the water temperature change according to the latitude or the depth of water in the case where the photoelectric conversion element 1 is used as a light emitting element under the sea. Further, at least one of the compound 122 and the compound 124 is preferably a compound which increases in volume by foaming or expansion. The increase in volume can more surely fill the broken part of the photoelectric conversion element 1.

The compound 122 preferably has two or more first reactive groups, and the compound 124 preferably has two or more second reactive groups which cause a polymerization with the first reactive groups. One of the first reactive group and the second reactive group preferably has at least one reactive group selected from the group consisting of a hydroxyl group and an amine group, and the other of the first reactive group and the second reactive group preferably has an isocyanate group.

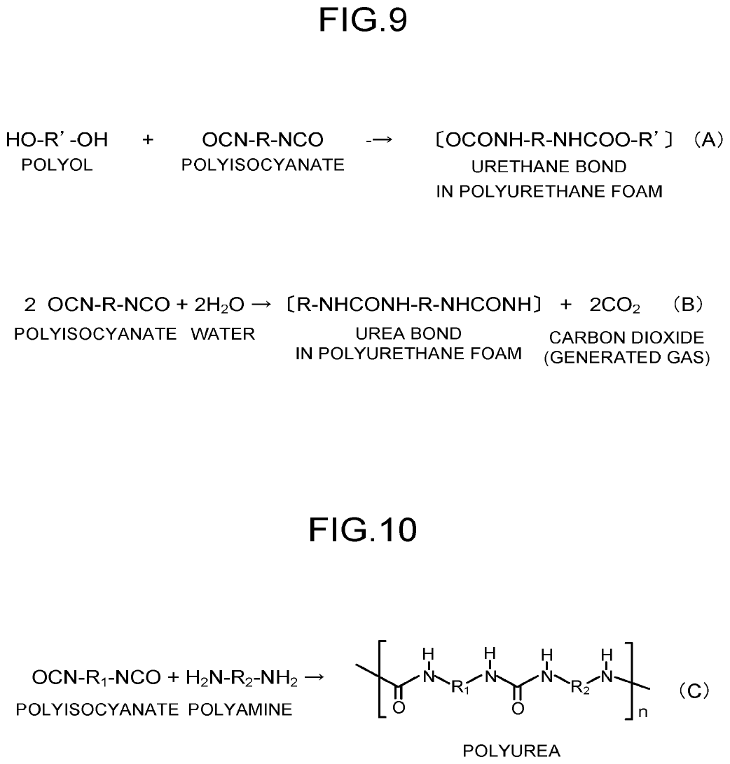

As the compound 122 and the compound 124, a precursor of foaming polyurethane or polyurea is preferable. FIG. 9 is a chart illustrating a typical chemical reaction formula of foaming polyurethane. As indicated in Formula (A), when polyol having hydroxyl groups at both terminals and polyisocyanate having isocyanate groups at both terminals are brought into contact with each other, a polymerization occurs to form a urethane bond to thereby form solid polyurethane. Further, as indicated in Formula (B), when polyisocyanate and water are brought into contact with each other, a chemical reaction occurs to generate carbon dioxide. When these two reactions occur almost simultaneously, foaming by carbon dioxide, namely, an increase in volume and solidification into polyurethane simultaneously occur. In other words, the use of polyol and polyisocyanate as the compound 122 and the compound 124 can form the polymer 120 to fill the broken part of the photoelectric conversion element 1.

As the water, water contained in the use environment can be used. In the atmosphere, water vapor in the atmosphere or water such as rain or snow can be used. The compound layer 12a and the compound layer 12b may contain water. Thus, even in the case where water is not contained in the use environment or the amount of water is insufficient, the photoelectric conversion element 1 is flawed or fractured or the encapsulating member 11 peels off, thereby offering the foaming (volume increasing) action almost simultaneously with the contact between the compound 122 and the compound 124 to able to more surely prevent the leakage of the harmful substance. Water is preferably contained in the compound layer containing polyol. If water is contained in the compound layer containing polyisocyanate, a reaction possibly starts at the stage before the photoelectric conversion element is broken.

FIG. 10 is a chart illustrating a typical chemical reaction formula of foaming polyurea. Polyol having hydroxyl groups at both terminals is used for polyurethane, whereas polyamine having amine groups at both terminals is used for polyurea. As indicated in Formula (C), when polyamine having amine groups at both terminals and polyisocyanate having isocyanate groups at both terminals are brought into contact with each other, a polymerization occurs to form a urea bond to thereby form solid polyurea. Polyisocyanate and water are brought into contact with each other to generate carbon dioxide, as with polyurethane.

Concurrently with the breakage of the photoelectric conversion element 1 and the breakage of the supporting member 121 and the supporting member 123, the compound 122 and the compound 124 which are provided in advance to separate from each other come into contact with each other to foam or expand and form the polymer 120, and thereby can fill the broken part of the photoelectric conversion element 1 with the polymer 120 so as to suppress the leakage of the harmful substance such as lead.

The photoelectric conversion element 1 can realize effects different depending on the difference in stacked structure. For example, in the photoelectric conversion element 1 illustrated in FIG. 1, the encapsulating member 11 is provided on the main entrance/exit side of the light 2 in the photoelectric conversion element 1, and the compound layer 12a and the compound layer 12b are provided on the side opposite to the main entrance/exit side of the light 2 in the photoelectric conversion element 1. Thus, when the compound 122 and the compound 124 contain materials absorbing the light 2, the decrease in light entrance/exit efficiency (namely, photoelectric conversion efficiency) can be suppressed. Further, since the compound layer 12a and the compound layer 12b are not irradiated with light, deterioration due to light irradiation of the compound layer 12a and the compound layer 12b can be suppressed. Further, prevention of the direct contact of the compound layer 12a and the compound layer 12b with the active layer 103 can suppress a deterioration of performances even in the case of the combination in which they deteriorate their performances with each other due to the contact.

In the photoelectric conversion element 1 illustrated in FIG. 2, the compound layer 12a and the compound layer 12b are provided on the main entrance/exit side of the light 2 in the photoelectric conversion element 1, and the encapsulating member 11 is provided on the side opposite to the main entrance/exit side of the light 2 in the photoelectric conversion element 1. The photoelectric conversion element 1 is often installed such that the main entrance/exit side of the light 2 faces the front side. For example, in the case of installing the photovoltaics on the roof, the photovoltaics is installed such that the main entrance/exit side of the light 2 faces the front side so that the sunlight is likely to be incident thereon. Accordingly, when the photoelectric conversion element 1 is flawed due to the hailstorm or the like, the photoelectric conversion element 1 is more likely to be flawed from the main entrance/exit side of the light 2. In the photoelectric conversion element 1 illustrated in FIG. 2, since the compound layer 12a and the compound layer 12b are provided on the main entrance/exit side of the light 2, namely, the side where the photoelectric conversion element 1 is more likely to be flawed, the probability of closing the broken part of the photoelectric conversion element 1 can be increased. Further, in the case of installing the photoelectric conversion element 1 with the main entrance/exit side of the light 2 directed in a direction opposite to the gravitational direction, for example, in the case of installing the photovoltaics to be directed in a direction of the sun (the direction opposite to the gravitational direction), and when the compound layer 12a and the compound layer 12b are flawed and at least one of the compound 122 and the compound 124 flows out, the compound flows toward the photoelectric conversion layer 10 according to the gravity. Therefore, the probability of closing the broken part of the photoelectric conversion element 1 can be increased. Further, the absence of the direct contact of the compound layers 12a and 12b with the active layer 103 can suppress the deterioration of performances in similar to the suppression of that of the photoelectric conversion element 1 illustrated in FIG. 1, even in the case of the combination in which they deteriorate their performances with each other due to the contact.

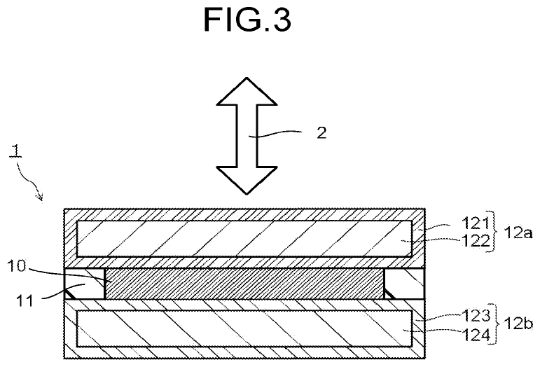

In the photoelectric conversion element illustrated in FIG. 3, the compound layer 12a is provided on the main entrance/exit side of the light 2 in the photoelectric conversion element 1, and the compound layer 12b is provided on the side opposite to the main entrance/exit side of the light 2 in the photoelectric conversion element 1. Thus, in the case where the compound 124 contains a substance absorbing the light 2, a decrease in light entrance/exit efficiency (namely, photoelectric conversion efficiency) can be suppressed. Further, since the compound layer 12b is not irradiated with light, a deterioration due to light irradiation of the compound layer 12b can be suppressed. Further, the absence of the direct contact of the compound layers 12a and 12b with the active layer 103 can suppress the deterioration of performances in similar to the suppression of that of the photoelectric conversion element 1 illustrated in FIG. 1 or FIG. 2, even in the case of the combination in which they deteriorate their performances with each other due to the contact.

In the photoelectric conversion element 1 illustrated in FIG. 4, the photoelectric conversion layer 10 is buried in the compound layer 12a. This can suppress the contact between the photoelectric conversion layer 10 and the substance in the use environment.

This eliminates the need for the encapsulating member 11 and can thus reduce the manufacturing cost and the weight and thickness.

In the photoelectric conversion element 1 illustrated in FIG. 5, the photoelectric conversion layer 10 is buried in the compound layer 12b. This can suppress the contact between the photoelectric conversion layer 10 and the substance in the use environment.

This eliminates the need for the encapsulating member 11 and can thus reduce the manufacturing cost and the weight and thickness.

### Second Embodiment

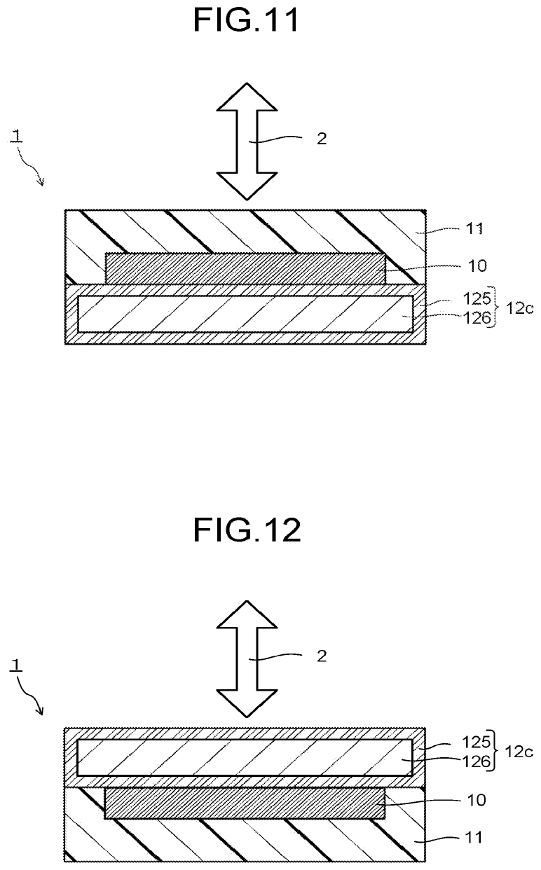

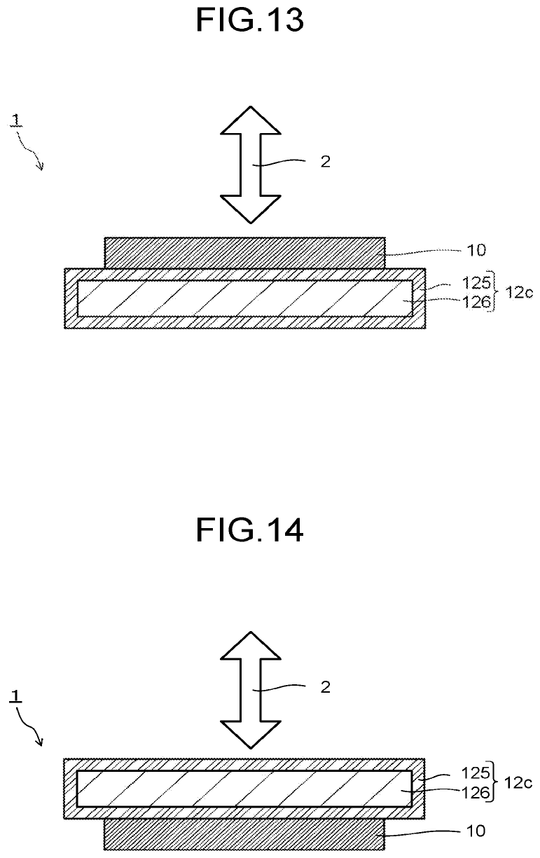

FIG. 11 to FIG. 14 are views illustrating structure examples of the photoelectric conversion element. Photoelectric conversion elements 1 illustrated in FIG. 11 and FIG. 12 each include a photoelectric conversion layer 10, an encapsulating member 11, and a compound layer 12c. Photoelectric conversion elements 1 illustrated in FIG. 13 and FIG. 14 each include a photoelectric conversion layer 10 and a compound layer 12c. Note that for the explanation of the photoelectric conversion layer 10 and the encapsulating member 11, the explanation of the photoelectric conversion element in the first embodiment is cited as needed. Further, the configuration of the photoelectric conversion element in the second embodiment can be appropriately combined with the configuration of the photoelectric conversion element in the first embodiment.

The compound layer 12c has a function as the leakage prevention layer which prevents leakage of a harmful substance accompanying the breakage of the photoelectric conversion element 1. The compound layer 12c includes, for example, a supporting member 125, and a compound 126 supported by the supporting member 125 and not in contact with the substance in the use environment of the photoelectric conversion element 1. The compound 126 is superimposed on the photoelectric conversion layer 10.

The supporting member 125 also has a function as a partition. As the supporting member 125, a material and a structure applicable to the supporting member 121 and the supporting member 123 can be applied.

The compound 126 comes into contact with the substance in the use environment accompanying, for example, the breakage of the photoelectric conversion element 1 to cause a polymerization to thereby form the polymer 120. The above substance is, for example, water or water vapor. The compound 126 is preferably in a liquid state or a gelatinous state in the use environment. Further, it is preferable to use, as the compound 126, a compound which increases in volume by foaming or expansion.

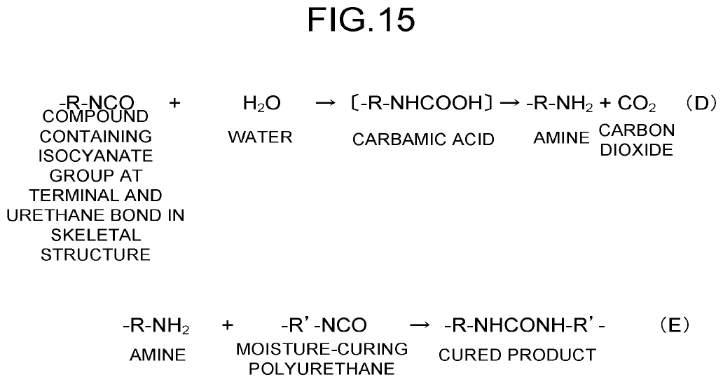

The compound 126 preferably has, for example, a skeletal structure containing a urethane bond and a reactive group containing an isocyanate group. As the compound 126, for example, a one-component moisture-curing polyurethane or polyurea is preferable. FIG. 15 is a chart illustrating a typical chemical reaction formula of the one-component moisture-curing polyurethane. When a compound having a terminal being an isocyanate group and containing a urethane bond in a skeletal structure comes into contact with water vapor existing as humid in the use environment or with water absorbed in the base on which the photoelectric conversion element 1 is installed, a carbamic acid is formed as expressed in Formula (D). The carbamic acid is chemically high active compound and thus decomposed into an amine compound and carbon dioxide as expressed in Formula (D). The amine compound reacts with an isocyanate group of the compound having a terminal being the isocyanate group and containing a urethane bond in a skeletal structure to form a urea bond as expressed in Formula (E) and thereby form solid polyurethane. In other words, use of the compound having a terminal being an isocyanate group and containing a urethane bond in a skeletal structure as the compound 126 can form the polymer 120 and fill the broken part of the photoelectric conversion element 1.

In the photoelectric conversion element in the second embodiment, only one kind of compound layer, a so-called one-component curing compound layer is used to suppress the leakage of the harmful substance accompanying the breakage of the photoelectric conversion element. This can decrease the kinds of necessary compound layers as compared with the two-component curing one and can thus reduce the manufacturing cost.

The photoelectric conversion element 1 can realize effects different depending on the difference in stacked structure. For example, in the photoelectric conversion element 1 illustrated in FIG. 11, the encapsulating member 11 is provided on the main entrance/exit side of the light 2 in the photoelectric conversion element 1 and the compound layer 12c is provided on the side opposite to the main entrance/exit side of the light 2 in the photoelectric conversion element 1. Thus, when the compound 126 contains a material absorbing the light 2, the decrease in light entrance/exit efficiency (namely, photoelectric conversion efficiency) can be suppressed. Further, since the compound layer 12c is not irradiated with light, a deterioration due to light irradiation of the compound layer 12c can be suppressed. Further, prevention of the direct contact of the compound layer 12c with the active layer 103 can suppress a deterioration of performances even in the case of the combination in which they deteriorate their performances with each other due to the contact.

In the photoelectric conversion element 1 illustrated in FIG. 12, the compound layer 12c is provided on the main entrance/exit side of the light 2 in the photoelectric conversion element 1 and the encapsulating member 11 is provided on the side opposite to the main entrance/exit side of the light 2 in the photoelectric conversion element 1. The photoelectric conversion element 1 is often installed such that the main entrance/exit side of the light 2 faces the front side. For example, in the case of installing the photovoltaics on the roof, the photovoltaics is installed such that the main entrance/exit side of the light 2 faces the front side so that the sunlight is likely to be incident thereon. Accordingly, when the photoelectric conversion element 1 is flawed due to the hailstorm or the like, the photoelectric conversion element 1 is more likely to be flawed from the main entrance/exit side of the light 2. In the photoelectric conversion element 1 illustrated in FIG. 12, since the compound layer 12c is provided on the main entrance/exit side of the light 2, namely, the side where the photoelectric conversion element 1 is more likely to be flawed, the probability of closing the broken part of the photoelectric conversion element 1 can be increased. Further, in the case of installing the photoelectric conversion element 1 with the main entrance/exit side of the light 2 directed in the direction opposite to the gravitational direction, for example, in the case of installing the photovoltaics to be directed in the direction of the sun (the direction opposite to the gravitational direction), and when the compound layer 12c is flawed and the compound 126 flows out, the compound flows toward the broken part of the photoelectric conversion layer 10 according to the gravity. Therefore, the probability of closing the broken part of the photoelectric conversion element 1 can be increased.

In the photoelectric conversion element 1 illustrated in FIG. 13, the photoelectric conversion layer 10 is provided on the main entrance/exit side of the light 2 in the photoelectric conversion element 1, and the compound layer 12c is provided on the side opposite to the main entrance/exit side of the light 2 in the photoelectric conversion element 1. Thus, in the case where the compound 126 contains a substance absorbing the light 2, a decrease in light entrance/exit efficiency (namely, photoelectric conversion efficiency) can be suppressed. Further, since the compound layer 12c is not irradiated with light, a deterioration due to light irradiation of the compound layer 12c can be suppressed. Further, prevention of the direct contact of the compound layer 12c with the active layer 103 can suppress deteriorations of their performances.

In the photoelectric conversion element 1 illustrated in FIG. 14, the compound layer 12c is provided on the main entrance/exit side of the light 2 in the photoelectric conversion element 1, and the photoelectric conversion layer 10 is provided on the side opposite to the main entrance/exit side of the light 2 in the photoelectric conversion element 1. The photoelectric conversion element 1 is often installed such that the main entrance/exit side of the light 2 faces the front side. For example, in the case of installing the photovoltaics on the roof, the photovoltaics is installed such that the main entrance/exit side of the light 2 faces the front side so that the sunlight is likely to be incident thereon. Accordingly, when the photoelectric conversion element 1 is flawed due to the hailstorm or the like, the photoelectric conversion element 1 is more likely to be flawed from the main entrance/exit side of the light 2. In the photoelectric conversion element 1 illustrated in FIG. 14, since the compound layer 12c is provided on the main entrance/exit side of the light 2, namely, the side where the photoelectric conversion element 1 is more likely to be flawed, the probability of closing the broken part of the photoelectric conversion element 1 can be increased. Further, in the case of installing the photoelectric conversion element 1 with the main entrance/exit side of the light 2 directed in the direction opposite to the gravitational direction, for example, in the case of installing the photovoltaics to be directed in the direction of the sun (the direction opposite to the gravitational direction), and when the compound layer 12c is flawed and the compound 126 flows out, the compound flows toward the broken part of the photoelectric conversion layer 10 according to the gravity. Therefore, the probability of closing the broken part of the photoelectric conversion element 1 can be increased.

### Third Embodiment

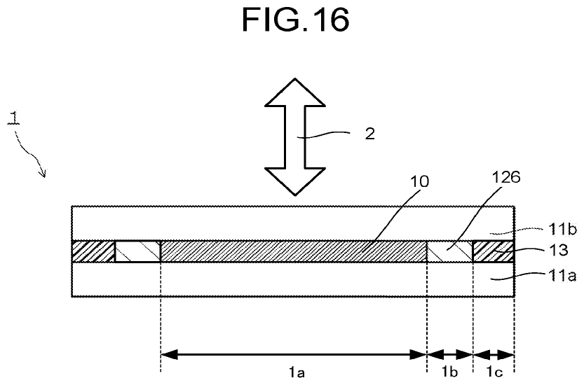

FIG. 16 is a view illustrating a structure example of the photoelectric conversion element. A photoelectric conversion element 1 illustrated in FIG. 16 includes a photoelectric conversion layer 10, a substrate 11a, a substrate 11b, a compound 126, and an adhesive layer 13. The photoelectric conversion element 1 illustrated in FIG. 16 includes a region 1a having the photoelectric conversion layer 10, a region 1b having the compound 126, and a region 1c having the adhesive layer 13.

The photoelectric conversion layer 10 is encapsulated with the substrate 11a, the substrate 11b, and the adhesive layer 13. Note that for the other explanation of the photoelectric conversion layer 10, the explanation of the photoelectric conversion elements in the first embodiment and the second embodiment is cited as needed. Further, the configuration of the photoelectric conversion element in the third embodiment can be appropriately combined with the configurations of the photoelectric conversion elements in the first embodiment and the second embodiment.

The substrate 11a and the substrate 11b are bonded together via the adhesive layer 13. The substrate 11a and the substrate 11b are composed using, but not limited to, an organic material such as polyethylene (PE), polyethylene terephthalate (PET) or an inorganic material such as glass, quartz, or sapphire. Further, the substrate 11a and the substrate 11b may have a hybrid structure composed of the organic material or an ultrathin inorganic material.

The compound 126 is provided between the photoelectric conversion layer 10 and the adhesive layer 13. The compound 126 is provided, for example, in contact with the substrate 11a or the substrate 11b. As the compound 126, for example, the same material as the compound illustrated in FIG. 15 can be applied.

The adhesive layer 13 bonds the substrate 11a and the substrate 11b together. The adhesive layer 13 is composed using, for example, a UV curing epoxy adhesive, a two-component curing acrylic adhesive or the like.

At the time when mechanical stress is applied on the photoelectric conversion element 1 illustrated in FIG. 16, the photoelectric conversion element 1 is broken and the adhesive layer 13 peels off in some cases. At this time, the adhesive layer 13 peels off and the compound 126 simultaneously comes into contact with the substance (water, water vapor or the like) in the use environment to cause a polymerization to thereby form the polymer 120, thereby closing the broken part of the photoelectric conversion element 1. This can prevent the photoelectric conversion layer 10 from coming into contact with moisture in the use environment or water such as rain or snow so as to suppress the leakage of the harmful substance such as lead.

### Fourth Embodiment

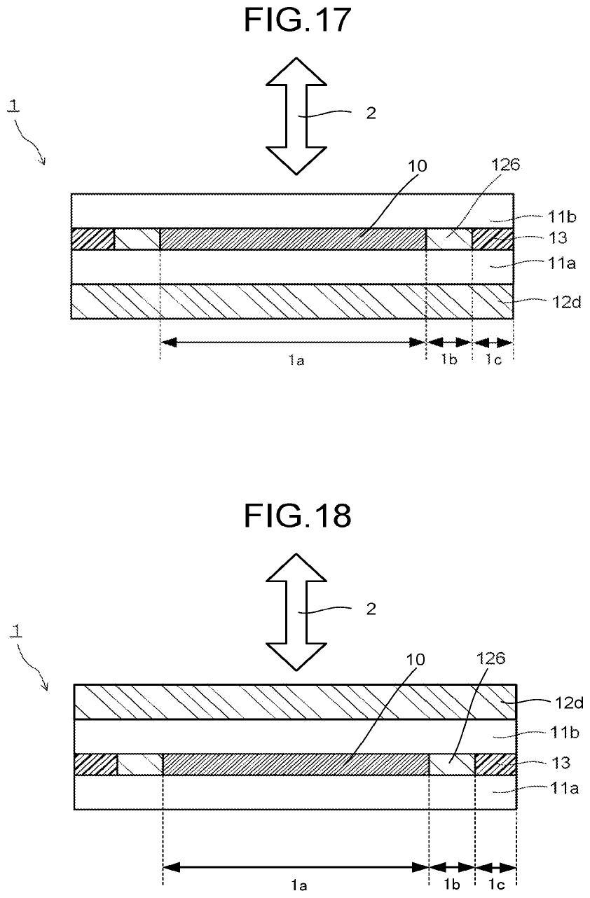

FIG. 17 to FIG. 20 are views illustrating structure examples of the photoelectric conversion element. Photoelectric conversion elements 1 illustrated in FIG. 17 to FIG. 20 each include a region 1a having a photoelectric conversion layer 10, a region 1b having a compound 126, and a region 1c having an adhesive layer 13.

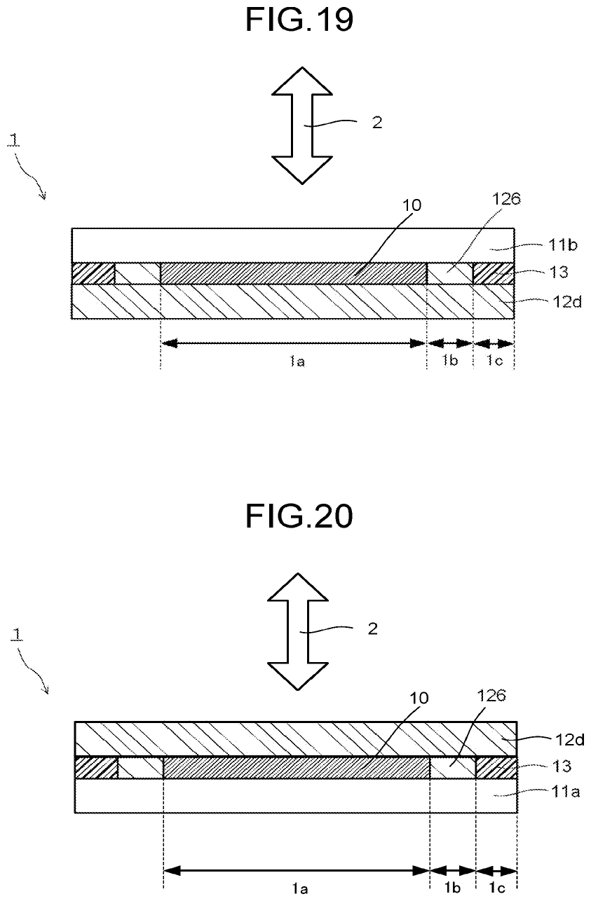

The photoelectric conversion elements 1 illustrated in FIG. 17 and FIG. 18 each include the photoelectric conversion layer 10, a substrate 11a, a substrate 11b, the compound 126, a compound layer 12d, and the adhesive layer 13. The photoelectric conversion element 1 illustrated in FIG. 19 includes the photoelectric conversion layer 10, a substrate 11b, the compound 126, a compound layer 12d, and the adhesive layer 13. The photoelectric conversion element 1 illustrated in FIG. 20 includes the photoelectric conversion layer 10, a substrate 11b, the compound 126, a compound layer 12d, and the adhesive layer 13. Note that for the explanation of the substrate 11a, the substrate 11b, and the compound 126, the explanation of the photoelectric conversion elements in the first embodiment and the second embodiment is cited as needed. Further, the configuration of the photoelectric conversion element in the fourth embodiment can be appropriately combined with the configurations of the photoelectric conversion elements in the first embodiment to the third embodiment.

The photoelectric conversion layers 10 illustrated in FIG. 17 and FIG. 18 are each encapsulated with the substrate 11a, the substrate 11b, and the adhesive layer 13, the photoelectric conversion layer 10 illustrated in FIG. 19 is encapsulated with the substrate 11b, the compound layer 12d, and the adhesive layer 13, and the photoelectric conversion layer 10 illustrated in FIG. 20 is encapsulated with the substrate 11a, the compound layer 12d, and the adhesive layer 13. For the other explanation of the photoelectric conversion layer 10, the explanation of the photoelectric conversion elements in the first embodiment and the second embodiment is cited as needed.

The compound layer 12d is provided in contact with the substrate 11a or the substrate 11b. As the compound layer 12d, for example, the same material and structure as those of the compound layer 12c can be applied.

The adhesive layers 13 illustrated in FIG. 17 and FIG. 18 each bond the substrate 11a and the substrate 11b together. The adhesive layer 13 illustrated in FIG. 19 bonds the substrate 11b and the compound layer 12d together. The adhesive layer 13 illustrated in FIG. 20 bonds the substrate 11a and the compound layer 12d together. The adhesive layer 13 is composed using, for example, a UV curing epoxy adhesive, a two-component curing acrylic adhesive or the like.

The photoelectric conversion elements 1 illustrated in FIG. 17 to FIG. 20 are each configured by combining the photoelectric conversion element in the second embodiment with the photoelectric conversion element in the third embodiment. This can exhibit the effect for all of the breakage modes of the photoelectric conversion element, namely, the mode of flawing the photoelectric conversion element 1, the mode of fracturing the photoelectric conversion element 1, and the mode of peeling the adhesive layer 13.

The photoelectric conversion element 1 can realize effects different depending on the difference in stacked structure. For example, in the photoelectric conversion element 1 illustrated in FIG. 17, the substrate 11b is provided on the main entrance/exit side of the light 2 in the photoelectric conversion element 1, and the compound layer 12d is provided on the side opposite to the main entrance/exit side of the light 2 in the photoelectric conversion element 1. Thus, in the case where the compound layer 12d contains a substance absorbing the light 2, a decrease in light entrance/exit efficiency (namely, photoelectric conversion efficiency) can be suppressed. Further, since the compound layer 12d is not irradiated with light, a deterioration due to light irradiation of the compound layer 12d can be suppressed. Further, prevention of the direct contact of the compound layer 12d with the active layer 103 can suppress a deterioration of performances even in the case of the combination in which they deteriorate their performances with each other due to the contact.

In the photoelectric conversion element 1 illustrated in FIG. 18, the compound layer 12d is provided on the main entrance/exit side of the light 2 in the photoelectric conversion element 1, and the substrate 11a is provided on the side opposite to the main entrance/exit side of the light 2 in the photoelectric conversion element 1. The photoelectric conversion element 1 is often installed such that the main entrance/exit side of the light 2 faces the front side. For example, in the case of installing the photovoltaics on the roof, the photovoltaics is installed such that the main entrance/exit side of the light 2 faces the front side so that the sunlight is likely to be incident thereon. Accordingly, when the photoelectric conversion element 1 is flawed due to the hailstorm or the like, the photoelectric conversion element 1 is more likely to be flawed from the main entrance/exit side of the light 2. In the photoelectric conversion element 1 illustrated in FIG. 18, since the compound layer 12d is provided on the main entrance/exit side of the light 2, namely, the side where the photoelectric conversion element 1 is more likely to be flawed, the probability of closing the broken part of the photoelectric conversion element 1 can be increased. Further, in the case of installing the photoelectric conversion element 1 with the main entrance/exit side of the light 2 directed in the direction opposite to the gravitational direction, for example, in the case of installing the photovoltaics to be directed in the direction of the sun (the direction opposite to the gravitational direction), and when the compound layer 12d is flawed and the compound 126 flows out, the compound flows toward the broken part of the photoelectric conversion layer 10 according to the gravity. Therefore, the probability of closing the broken part of the photoelectric conversion element 1 can be increased.

In the photoelectric conversion element 1 illustrated in FIG. 19, the substrate 11b and the compound layer 12d are bonded together via the adhesive layer 13. This can omit the substrate 11a and can thus reduce the manufacturing cost.

In the photoelectric conversion element 1 illustrated in FIG. 20, the substrate 11a and the compound layer 12d are bonded together via the adhesive layer 13. This can omit the substrate 11b and can thus reduce the manufacturing cost.

### EXAMPLES

### Example 1

On a PEN substrate having a thickness of 125 μm, an ITO film having a thickness of 150 nm was formed as a transparent electrode. As an intermediate layer provided on the transparent electrode side, a stack of nanoparticles of nickel oxide was formed.

As the active layer, a perovskite layer was formed. As a perovskite material, CH₃NH₃PbI₃ was used. As a solvent of perovskite material ink, a mixed solvent of dimethylformamide (DMF) and dimethyl sulfoxide (DMSO) at 1:1 was used. After the perovskite material ink was applied, the substrate was immersed in a vessel storing chlorobenzene. Thereafter, the substrate was taken out and heated at a temperature of 80° C. for 60 minutes, whereby the perovskite layer was formed. Its thickness was about 250 nm.

As a first intermediate layer provided on a counter electrode side, PC60BM ([6,6]-phenyl C61 butyric acid methyl ester) was formed. As a solvent of PC60BM ink, monochlorobenzene was used. After the PC60BM ink was applied, it was naturally dried. Its thickness was about 50 nm.

A second intermediate layer provided on the counter electrode side was formed by vacuum deposition of BCP (2,9-dimethyl-4,7-diphenyl-1,10-phenanthroline) in a thickness of about 20 nm. Further, the counter electrode was formed by vacuum deposition of Ag in a thickness of about 150 nm.

A PET film for encapsulating was pasted to the face on the side where the counter electrode was formed, thereby producing an organic/inorganic hybrid perovskite photoelectric conversion element.

On the side of the encapsulating PET film of the photovoltaics element, a polyisocyanate compound was applied, and the PET film was pasted thereon to form a compound layer containing the polyisocyanate compound. Then, a polyol compound was further applied thereon, and the PET film was pasted thereon to form a compound layer containing the polyol compound. For the polyisocyanate compound and the polyol compound, a commercially available two-component foaming polyurethane material was used. Thus, the photoelectric conversion element was completed.

A damage test was carried out using the completed photoelectric conversion element. Cutting the photoelectric conversion element using a cutter knife, the polyisocyanate compound and the polyol compound flowed out. Then, water was poured onto the photoelectric conversion element in imitation of rainfall. As a result, a mixture of the polyisocyanate compound and the polyol compound foamed to be increased in volume, thereby closing the cut part of the perovskite layer. Thereafter, the foamed mixture of the polyisocyanate compound and the polyol compound cured.

Pouring water in imitation of rainfall onto the photoelectric conversion element whose cut part was filled with the foamed and cured polyurethane, the lead in the perovskite layer did not leak. In the case where the perovskite layer dissolves out in water, yellow PbI₂ dissolves out in water, so that the water changes in color to yellow, but the color did not change and therefore the leakage of the harmful substance was not confirmed in this example.

### Example 2

An organic/inorganic hybrid perovskite photoelectric conversion element was produced as in Example 1. The compound layer was formed by applying a compound having a urethane bond in a skeletal structure and having an isocyanate group at a terminal on the side of the encapsulating PET film of the photovoltaics element, and pasting a PET film thereon. For the compound having a urethane bond in a skeletal structure and having an isocyanate group at a terminal, a commercially available one-component moisture-curing polyurethane material was used.

The photoelectric conversion efficiency was measured while irradiating the photoelectric conversion element with simulated sunlight, consequently the photoelectric conversion efficiency was 9.2%. A damage test was carried out using the completed photoelectric conversion element. Cutting the photoelectric conversion element using a cutter knife, the compound having a urethane bond in a skeletal structure and having an isocyanate group at a terminal flowed out and filled the cut part of the perovskite layer. Thereafter, the flowed compound cured.

Pouring water in imitation of rainfall onto the photoelectric conversion element whose cut part was filled with the cured polyurethane, the lead in the perovskite layer never dissolved out.

### Example 3

An organic/inorganic hybrid perovskite photovoltaics element was produced as in Example 1. The compound layer was formed by applying a compound having a urethane bond in a skeletal structure and having an isocyanate group at a terminal on the side of the PEN film for substrate of the photovoltaics element, and pasting a PET film thereon. For the compound having a urethane bond in a skeletal structure and an isocyanate group at a terminal, a commercially available one-component moisture-curing polyurethane material was used.

The photoelectric conversion efficiency was measured while irradiating the photoelectric conversion element with simulated sunlight, consequently the photoelectric conversion efficiency was 8.5% slightly lower than 9.2% in Example 2. This example is different from Example 2 in that the compound layer and the PET film are provided on the side of irradiation with simulated sunlight, and this structure can absorb and reflect the simulated sunlight. As a result, the intensity of the simulated sunlight to the photoelectric conversion layer reduced and the photoelectric conversion efficiency slightly decreased.

A damage test was carried out using the completed photoelectric conversion element. Cutting the photoelectric conversion element using a cutter knife, the compound having a urethane bond in a skeletal structure and having an isocyanate group at a terminal flowed out and filled the cut part of the perovskite layer. Thereafter, the flowed compound cured.

Pouring water in imitation of rainfall onto the photoelectric conversion element whose cut surface was filled with the cured polyurethane, the lead in the perovskite layer never dissolved out.

### Example 4

The process was performed as in Example 1 until the step of forming Ag as the counter electrode. An adhesive was applied in a frame shape only at the outer peripheral portion of the PEN film for substrate. This is a dam forming step in a so-called dam and fill method. Inside the adhesive in a dam shape formed in the frame shape, a compound having a urethane bond in a skeletal structure and having an isocyanate group at a terminal was filled. This is a so-called a fill step. A compound layer was formed by pasting a PET film thereon. For the compound having a urethane bond in a skeletal structure and having an isocyanate group at a terminal, a commercially available one-component moisture-curing polyurethane material was used. Thus, the photoelectric conversion element was completed.

A damage test was carried out using the completed photoelectric conversion element. A cutter knife was inserted into a pasting interface between the PEN film for substrate and the PET film to peel the adhesive at the pasting interface between the PEN film for substrate and the PET film. As a result, the compound having a urethane bond in a skeletal structure and having an isocyanate group at a terminal was exposed to the atmosphere and cured.

Pouring water in imitation of rainfall onto the photoelectric conversion element whose peeled part was filled again with the cured polyurethane, the lead in the perovskite layer never dissolved out.

### Comparative Example 1

An organic/inorganic hybrid perovskite photoelectric conversion element was produced as in Example 1 except that the above compound layer was not provided. A damage test was carried out using the produced photoelectric conversion element. The photoelectric conversion element was cut using a cutter knife. Pouring water in imitation of rainfall, the perovskite layer gradually changed in color from the cut surface from black to yellow. In other words, black CH₃NH₃PbI₃ was decomposed into yellow PbI₂. Further, the appearance that yellow PbI₂ dissolved out into water from the cut surface was observed.

While certain embodiments of the present invention have been described, these embodiments have been presented by way of example only, and are not intended to limit the scope of the inventions. Indeed, the novel embodiments described herein may be embodied in a variety of other forms; furthermore, various omissions, substitutions and changes may be made without departing from the spirit of the inventions. The inventions described in the accompanying claims and their equivalents are intended to cover such forms or modifications as would fall within the scope and spirit of the inventions.

What is claimed is:

1. A photoelectric conversion element comprising:
a photoelectric conversion layer;
a first compound layer including a first supporting member and a first compound, the first compound being supported by the first supporting member, being not in contact with from the photoelectric conversion layer, and being liquid or gelatinous in an environment to use the element; and
a second compound layer including a second supporting member and a second compound, the second compound being supported by the second supporting member, being not in contact with from the photoelectric conversion layer and the first compound, and being liquid or gelatinous in the environment.

2. A photoelectric conversion element comprising:
a photoelectric conversion layer;
a first compound layer including a first supporting member and a first compound, the first compound being supported by the first supporting member and having two or more first reactive groups; and
a second compound layer including a second supporting member and a second compound, the second compound being supported by the second supporting member, having two or more second reactive groups, and being not in contact with the first compound, wherein
contact between the first and second compounds in response to breakage of the element causes a polymerization between the first and second reactive groups to form a polymer.

3. The element according to claim 2, wherein:
one of the first and second reactive groups includes at least one reactive group selected from the group consisting of a hydroxyl group and an amine group; and
another of the first and the second reactive groups includes an isocyanate group.

4. The element according to claim 1, wherein
at least one layer selected from the group consisting of the first and second compound layers includes water.

5. The element according to claim 1, wherein
the contact between the first and second compounds causes a mixture thereof to foam or expand.

6. A photoelectric conversion element comprising:
a photoelectric conversion layer; and
a compound layer including a supporting member and a compound, the compound being supported by the supporting member, having two or more reactive groups, and being not in contact with a substance in an environment to use the element, wherein
contact between the compound and the substance in response to breakage of the element causes a polymerization therebetween to form a polymer.

7. The element according to claim 6, further comprising:
a first substrate; and
a second substrate bonded on the first substrate via an adhesive layer, wherein:
at least one substrate selected from the group consisting of the first and second substrates is transparent to light;
the photoelectric conversion layer is encapsulated with the first substrate, the second substrate, and the adhesive layer; and
the compound is provided between the photoelectric conversion layer and the adhesive layer.

8. The element according to claim 6, further comprising:
a substrate;
a third compound having two or more reactive groups; and
an adhesive layer, wherein:
at least one selected from the group consisting of the substrate and the compound layer is transparent to light;
the photoelectric conversion layer is encapsulated with the substrate, the compound layer, and the adhesive layer;
the third compound is provided between the photoelectric conversion layer and the adhesive layer; and
contact between the third compound and the substance in response to the breakage causes a polymerization therebetween to form a polymer.

9. The element according to claim 6, wherein
the compound has:
a skeletal structure including a urethane bond; and
a reactive group including an isocyanate group.

10. The element according to claim 8, wherein
the compound and the third compound has:
a skeletal structure including a urethane bond; and
a reactive group including an isocyanate group.

11. The element according to claim 6, wherein
the substance includes water or water vapor.

12. The element according to claim 1, wherein
the photoelectric conversion layer contains a compound expressed by a composition formula ABX₃,
where A denotes at least one cation selected from the group consisting of monovalent cations, B denotes at least one cation selected from the group consisting of divalent cations including a lead ion, and X denotes at least one halogen ion selected from the group consisting of monovalent halogen ions.
